(19) United States
(12) Patent Application Publication
(10) Pub. No.: US 2025/0191913 A1
(43) Pub. Date: Jun. 12, 2025

(54) SEMICONDUCTOR DEVICE AND METHOD FOR MANUFACTURING SEMICONDUCTOR DEVICE

(71) Applicant: Japan Display Inc., Tokyo (JP)

(72) Inventors: Hayata AOKI, Tokyo (JP); Masumi NISHIMURA, Tokyo (JP)

(73) Assignee: Japan Display Inc., Tokyo (JP)

(21) Appl. No.: 19/059,392

(22) Filed: Feb. 21, 2025

Related U.S. Application Data
(63) Continuation of application No. PCT/JP2023/021217, filed on Jun. 7, 2023.

(30) Foreign Application Priority Data
Sep. 1, 2022 (JP) 2022-139270

(51) Int. Cl. H01L 21/02; H10D 30/47; H10D 62/85; H10H 20/812; H10H 20/825

(52) U.S. Cl. CPC H01L 21/02516; H01L 21/02422; H01L 21/02502; H01L 21/02513; H01L 21/0254; H01L 21/02631; H10D 30/475; H10D 62/8503; H10H 20/812; H10H 20/825

(57) ABSTRACT

A semiconductor device includes an amorphous substrate with an insulating surface; an orientation pattern on the amorphous substrate; and a semiconductor pattern including gallium nitride on a top surface of the orientation pattern. The orientation pattern includes a first pattern portion with a side surface having a first angle relative to a bottom surface, and a second pattern portion with a side surface having a second angle smaller than the first angle relative to the bottom surface and located lower than the first pattern portion.

### CROSS REFERENCE TO RELATED APPLICATIONS

This application is a Continuation of International Patent Application No. PCT/JP2023/021217, filed on Jun. 7, 2023, which claims the benefit of priority to Japanese Patent Application No. 2022-139270, filed on Sep. 1, 2022, the entire contents of which are incorporated herein by reference.

### FIELD

An embodiment of the present invention relates to a semiconductor device using a semiconductor layer containing gallium nitride and a method for manufacturing thereof.

### BACKGROUND

In recent years, a semiconductor device using a semiconductor layer (hereinafter referred to as “gallium nitride semiconductor layer”) containing gallium nitride (GaN) has been developed. For example, a transistor element such as a HEMT (High Electron Mobility Transistor) and a light-emitting element such as an LED (Light-emitting Diode) are known as the semiconductor device using the gallium nitride semiconductor layer. In particular, demand for a light-emitting device using the light-emitting diode (LED) for each pixel is high, and a technique for forming a highly crystalline gallium nitride semiconductor layer on a substrate other than a silicon substrate has been rapidly developed. For example, Japanese laid-open patent publication No. 2018-168029 discloses a technique in which a buffer layer is formed on an insulating substrate such as a sapphire substrate or a quartz glass substrate, an insulating pattern is formed on the buffer layer, and the gallium nitride semiconductor layer is formed on the buffer layer and the insulating pattern.

### SUMMARY

A semiconductor device according to an embodiment of the present invention includes an amorphous substrate with an insulating surface; an orientation pattern on the amorphous substrate; and a semiconductor pattern including gallium nitride on a top surface of the orientation pattern. The orientation pattern includes a first pattern portion with a side surface having a first angle relative to a bottom surface, and a second pattern portion with a side surface having a second angle smaller than the first angle relative to the bottom surface and located lower than the first pattern portion.

A method for manufacturing a semiconductor device according to an embodiment of the present invention includes forming an orientation layer on an amorphous substrate having an insulating surface; forming an orientation pattern having an inclined side surface with respect to a bottom surface by wet etching the orientation layer; forming a semiconductor layer including gallium nitride on the insulating surface and the orientation pattern; and forming a semiconductor pattern on a top surface of the orientation pattern by etching the semiconductor layer including gallium nitride.

A method for manufacturing a semiconductor device according to an embodiment of the present invention includes forming an orientation layer on an amorphous substrate having an insulating surface; forming an orientation pattern having an inclined side surface with respect to a bottom surface by wet etching the orientation layer; forming a first pattern portion with a side surface having a first angle relative to a bottom surface, and a second pattern portion with a side surface having a second angle smaller than the first angle relative to the bottom surface and located lower than the first pattern portion by etching the orientation pattern; forming a semiconductor layer including gallium nitride on the insulating surface and the orientation pattern; and forming a semiconductor pattern on a top surface of the orientation pattern by etching the semiconductor layer including gallium nitride.

A method for manufacturing a semiconductor device according to an embodiment of the present invention include forming a buffer layer on an amorphous substrate having an insulating surface; forming an orientation layer on the buffer layer, the orientation layer being made of a different material from the buffer layer; forming a first pattern portion with an inclined side surface having a first angle with respect to a bottom surface by etching the orientation layer; forming a second pattern portion with an inclined side surface having a second angle smaller than the first angle with respect to the bottom surface by etching the buffer layer; forming a semiconductor layer including gallium nitride on the insulating surface, the first pattern portion and the second pattern portion; and forming a semiconductor pattern on a top surface of the first pattern portion by etching the semiconductor layer including gallium nitride.

### BRIEF DESCRIPTION OF THE DRAWINGS

FIG. 1 is an end face view showing a method for manufacturing a semiconductor device using a gallium nitride semiconductor layer in the first embodiment.

FIG. 2 is an end face view showing a method for manufacturing a semiconductor device using a gallium nitride semiconductor layer in the first embodiment.

FIG. 3 is an end face view showing a method for manufacturing a gallium nitride semiconductor layer in the first embodiment.

FIG. 4 is an end face view showing a method for manufacturing a semiconductor device using a gallium nitride semiconductor layer in the first embodiment.

FIG. 5 is an end face view showing a method for manufacturing a semiconductor device using a gallium nitride semiconductor layer in the first embodiment.

FIG. 6 is an end face view showing a method for manufacturing a semiconductor device using a gallium nitride semiconductor layer in the first embodiment.

FIG. 7 is an end face view showing a semiconductor device including a gallium nitride semiconductor layer in the first embodiment.

FIG. 8 is a plan face view showing a semiconductor device including a gallium nitride semiconductor layer in the first embodiment.

FIG. 9 is an end face view showing a method for manufacturing a semiconductor device using a gallium nitride semiconductor layer in a second embodiment.

FIG. 10 is an end face view showing a method for manufacturing a semiconductor device using a gallium nitride semiconductor layer in the second embodiment.

FIG. 11 is an end face view showing a method for manufacturing a semiconductor device using a gallium nitride semiconductor layer in the second embodiment.

FIG. 12 is an end face view showing a method for manufacturing a semiconductor device using a gallium nitride semiconductor layer in the second embodiment.

FIG. 13 is an end face view showing a method for manufacturing a semiconductor device using a gallium nitride semiconductor layer in the second embodiment.

FIG. 14 is an end face view showing a method for manufacturing a semiconductor device using a gallium nitride semiconductor layer in the second embodiment.

FIG. 15 is an end face view showing a method for manufacturing a semiconductor device using a gallium nitride semiconductor layer in a third embodiment.

FIG. 16 is an end face view showing a method for manufacturing a semiconductor device using a gallium nitride semiconductor layer in the third embodiment.

FIG. 17 is an end face view showing a method for manufacturing a semiconductor device using a gallium nitride semiconductor layer in the third embodiment.

FIG. 18 is an end face view showing a method for manufacturing a semiconductor device using a gallium nitride semiconductor layer in the third embodiment.

FIG. 19 is an end face view showing a method for manufacturing a semiconductor device using a gallium nitride semiconductor layer in the third embodiment.

FIG. 20 is an end face view showing a method for manufacturing a semiconductor device using a gallium nitride semiconductor layer in the third embodiment.

FIG. 21 is an end face view showing a method for manufacturing a semiconductor device using a gallium nitride semiconductor layer in the third embodiment.

FIG. 22 is an end face view showing a semiconductor device including a gallium nitride semiconductor layer in a fourth embodiment.

### DESCRIPTION OF EMBODIMENTS

As in the prior art, generally, a gallium nitride semiconductor layer is formed by epitaxial growth at a temperature exceeding 1000° C. using a sapphire substrate or a quartz glass substrate having a heat resistance of 1000° C. or higher. However, considering applications to a light-emitting display device, the use of an expensive sapphire substrate or quartz glass substrate is problematic in that it hinders the increase in the area of a display screen. Furthermore, in the processing at a temperature exceeding 1000° C., time is required for a temperature increase at the start of the processing and a temperature decrease at the end of the processing, and there is also a problem that the throughput is lowered.

An object of an embodiment of the present invention is to form a highly crystalline gallium nitride semiconductor layer on an inexpensive amorphous substrate.

In addition, an object of an embodiment of the present invention is to provide a high-throughput semiconductor device using the gallium nitride semiconductor layer having high crystallinity.

Hereinafter, embodiments of the present invention will be described with reference to the drawings and the like. However, the present invention can be implemented in various forms without departing from the gist thereof. The present invention is not to be construed as being limited to the description of the embodiments exemplified below. In the drawings, the widths, thicknesses, shapes, and the like of the respective portions may be schematically represented in comparison with actual embodiments for clarity of explanation. However, the drawings are merely examples, and do not limit the interpretation of the present invention.

In describing an embodiment of the present invention, a direction from a substrate toward a semiconductor layer is referred to as “upper”, and a reverse direction thereof is referred to as “lower”. However, the expression “on” or “under” merely describes the vertical relationship of each element. In addition, the expression “on” or “under” includes not only the case where a third element is interposed between a first element and a second element, but also the case where it is not interposed. Furthermore, the term “on” or “under” includes not only the case where the elements overlap in a plan view, but also the case where they do not overlap.

In describing the embodiments of the present invention, elements having the same functions as those described above may be denoted by the same reference signs or the same reference signs with letters or the like, and descriptions thereof may be omitted. Furthermore, in the case where a part of an element needs to be described separately, a symbol such as a letter may be attached to a symbol indicating the element to distinguish the element. However, in the case where it is not necessary to distinguish each part of the element, the description will be made using only the reference sign indicating the element.

In describing embodiments of the present invention, the expressions such as “α includes A, B, or C,” “a includes any of A, B, and C,” and “a includes one selected from a group consisting of A, B, and C” do not exclude the case where a includes a plurality of combinations of A to C unless otherwise specified. Furthermore, these expressions do not exclude the case where a includes other elements.

### First Embodiment

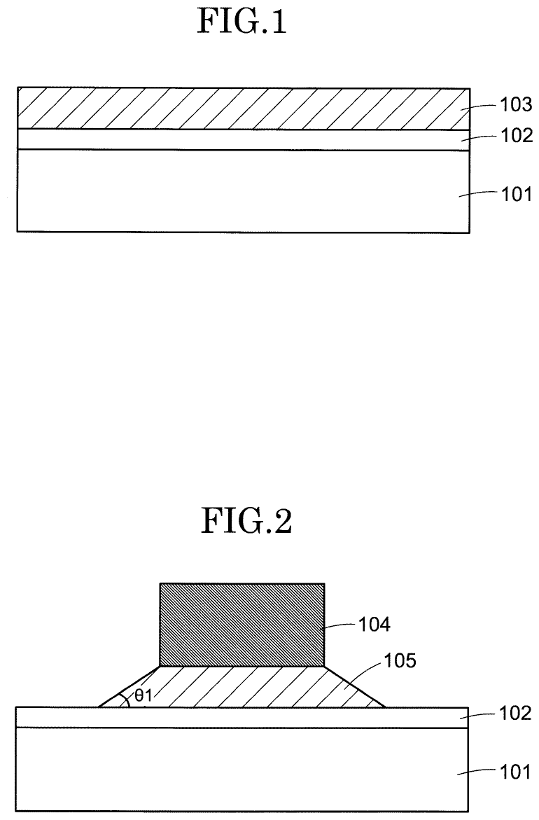

FIG. 1 to FIG. 6 are end face views showing a method for manufacturing a semiconductor device including a gallium nitride semiconductor layer according to the first embodiment. In particular, FIG. 1 to FIG. 6 show examples of forming a semiconductive pattern including the gallium nitride layer on an amorphous substrate. In addition, although FIG. 1 to FIG. 6 show examples of forming a single semiconductor pattern, in practice, a plurality of semiconductor patterns is formed on the substrate.

First, as shown in FIG. 1, a base layer 102 is formed on an amorphous substrate 101. For example, a glass substrate can be used as the amorphous substrate 101. It is preferable that the glass substrate has a low content of alkaline components, a low coefficient of thermal expansion, a high strain point, and a high surface-flatness. For example, the content of an alkali metal (such as sodium) is preferably 0.1% or less, the thermal expansion coefficient is preferably lower than 50×10⁻⁷/° C., and the strain point is preferably 600° C. or higher. As will be described later, in the present embodiment, since the gallium nitride semiconductor layer is formed by a sputtering method, a glass substrate having lower heat resistance than that of the sapphire substrate or the quartz substrate can be used. Such a glass substrate is less expensive than the sapphire substrate and the quartz substrate, and is also suitable for increasing the area of a mother glass. However, the amorphous substrate 101 of the present embodiment is not limited to the glass substrate, and may be a resin substrate such as a polyimide substrate, an acryl substrate, a siloxane substrate, or a fluororesin substrate.

The base layer 102 serves as a protective layer to prevent an impurity from entering from the amorphous substrate 101. For example, the base layer 102 is composed of one or a plurality of layers selected from a silicon nitride layer, a silicon oxide layer, an aluminum nitride layer, and an aluminum oxide layer.

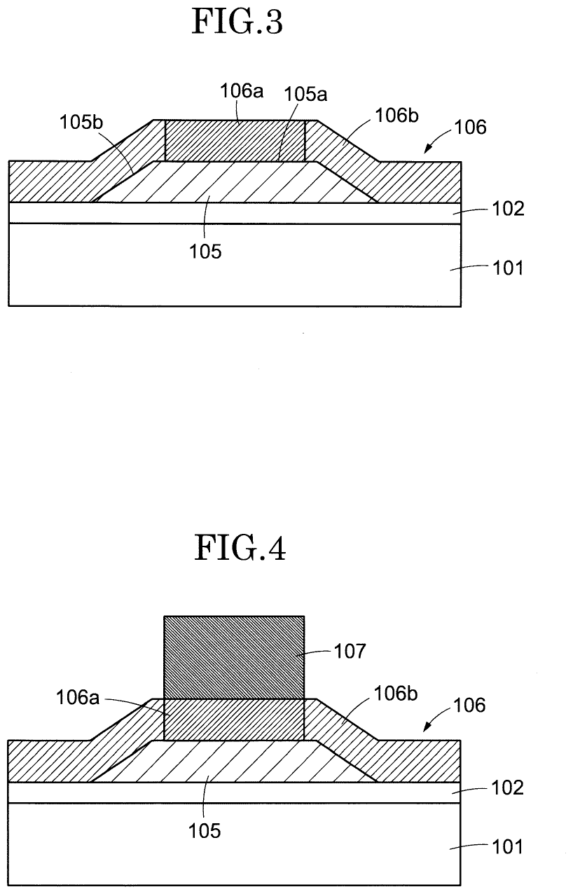

An orientation layer 103 is formed on the base layer 102. The orientation layer 103 has a function of improving the orientation property of the crystal of a gallium nitride layer 106 when forming the gallium nitride layer 106 (see FIG. 3) to be described later.

The orientation layer 103 may be conductive or insulating but preferably has crystallinity oriented along a specific axis (e.g., c-axis). The orientation layer 103 is preferably crystals with rotational symmetry. For example, the crystal surface of the orientation layer 103 preferably has six-fold rotational symmetry. In addition, the orientation layer 103 preferably has a hexagonal close-packed structure, a face-centered cubic structure, or a structure equivalent thereto. In this case, the structure equivalent to the hexagonal close-packed structure or the face-centered cubic structure includes a crystal structure in which the c-axis does not become 90 degrees with respect to the a-axis and the b-axis. The orientation layer 103 having the hexagonal close-packed structure or the structure equivalent thereto is preferably oriented in a (0001) direction, that is, the c-axis direction, with respect to the amorphous substrate 101. The orientation layer 103 having the face-centered cubic structure or the structure similar thereto is preferably oriented in a (111) direction with respect to the amorphous substrate 101.

Since the surface condition of the orientation layer 103 affects the crystallinity of the gallium nitride layer 106, which will be described later, the surface of the orientation layer 103 is preferably flat. For example, the orientation layer 103 preferably has a surface arithmetic mean roughness (Ra) of less than 2.3 nm.

A conductive orientation layer or an insulating orientation layer can be used as the orientation layer 103 described above. For example, titanium (Ti), titanium nitride (TiNx), titanium oxide (TiOx), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), BiLaTiO, BiFeO, BaFeO, ZnFeO, or PMnN-PZT can be used as the conductive orientation layer. In particular, titanium, graphene, and zinc oxide are preferably used as the conductive orientation layer. In the present embodiment, a titanium layer is used as the orientation layer 103.

In addition, aluminum nitride (AlN), aluminum oxide (Al₂O₃), lithium niobate (LiNbO), BiLaTiO, SrFeO, BiFeO, BaFeO, ZnFeO, PMnN-PZT, biological apatite (BAp), or the like can be used as the insulating orientation layer. In particular, aluminum nitride or aluminum oxide is preferable as the insulating orientation layer. In the case where the insulating orientation layer is used as the orientation layer 103 in the present embodiment, an aluminum nitride layer is preferably used.

For example, a thickness of the orientation layer 103 is 50 nm or more (preferably, 50 nm or more and 100 nm or less). The orientation layer 103 can be formed by any method. For example, the orientation layer 103 can be formed by the sputtering method, a CVD method, a vacuum vapor deposition method, an electron beam deposition method, or the like.

Next, as shown in FIG. 2, the orientation layer 103 is etched using a resist mask 104 to form an orientation pattern 105. The orientation pattern 105 has a gradient (hereinafter referred to as a “taper”) in which an angle of the side surface with respect to the bottom surface is θ1. In this case, in the present embodiment, since the wet etching method is used for etching the orientation layer 103, the taper angle θ1 of the orientation pattern 105 can be set to 20° or more and 50° or less (preferably, 30° or more and 40° or less). In the case where the dry etching method is used for etching the orientation layer 103, the taper tends to be large, and the taper angle θ1 is 60° or more depending on the conditions. However, for example, if the taper angle θ1 of the orientation pattern 105 is 60° or more, when the gallium nitride layer 106 to be described later is etched, an etching residue (a residue of the gallium nitride layer 106) may occur near the lower end of the tapered portion (near the boundary between the base layer 102 and the orientation pattern 105). In the present embodiment, in order to prevent such an etching residue, the wet etching method is adopted so that the taper angle θ1 of the orientation pattern 105 is 20° or more and 50° or less.

In the case where the orientation layer 103 is the conductive orientation layer, a wiring or electrode may be formed using the orientation layer 103 when the orientation pattern 105 is formed. For example, in a region where the semiconductor device is formed, the orientation layer 103 may be etched to be used as the orientation pattern 105, and in another region, the orientation layer 103 may be etched to be used as the wiring or electrode. In this case, the wiring or electrode formed by etching the orientation layer 103 is made of the same material and the same layer formed by the same process as the orientation pattern 105.

Next, as shown in FIG. 3, the gallium nitride layer 106 is formed to cover the orientation pattern 105. In the present embodiment, the gallium nitride layer 106 is formed as the semiconductor layer by the sputtering method. Specifically, for example, the gallium nitride layer 106 is formed by the sputtering method in which the amorphous substrate 101 having an insulating surface (in this case, the amorphous substrate 101 in which the base layer 102 is arranged) is heated to 25° C. or higher and 600° C. or lower. That is, the gallium nitride layer 106 is formed at a temperature below the strain point of the amorphous substrate 101. The gallium nitride is usually formed by a MOCVD method (Metal Organic Chemical Vapor Deposition). However, the MOCVD method is not suitable as a method for depositing gallium nitride due to the high process temperature, considering the heat resistance of the amorphous substrate 101. However, in the present embodiment, the gallium nitride layer 106 can be formed on the inexpensive amorphous substrate 101 by using the sputtering method.

For example, the gallium nitride layer 106 is formed by performing sputtering using a sintered body of gallium nitride as a sputtering target and argon (Ar) or a mixed gas of argon (Ar) and nitrogen (N2) as a sputtering gas. For example, a two-pole sputtering method, a magnetron sputtering method, a dual magnetron sputtering method, an opposing target sputtering method, an ion beam sputtering method, or an inductively coupled plasma (ICP) sputtering method can be applied as the sputtering method.

The conductivity type of the gallium nitride layer 106 may be substantially intrinsic, or may have n-type conductivity or p-type conductivity. The gallium nitride having n-type conductivity may not contain a dopant for valence control, or may have silicon (Si) or germanium (Ge) added as an n-type dopant. In the gallium nitride having p-type conductivity, one element selected from magnesium (Mg), zinc (Zn), cadmium (Cd), and beryllium (Be) may be added as a p-type dopant. In the case where the n-type dopant is added to the gallium nitride layer 106, the carrier concentration is preferably 1×10¹⁸/cm³ or more. In the case where the p-type dopant is added to the gallium nitride layer 106, the carrier concentration is preferably 5×10¹⁶/cm³ or more. Furthermore, in the case where the gallium nitride layer 106 is made substantially intrinsic, zinc (Zn) may be contained as a dopant.

In addition, the gallium nitride layer 106 may contain one or more elements selected from indium (In), aluminum (Al), and arsenic (As). The bandgap of the gallium nitride layer 106 can be adjusted by these elements.

As described above, in the present embodiment, the gallium nitride layer 106 is formed on the amorphous substrate 101 on which the orientation pattern 105 is formed. In this case, the gallium nitride layer 106 formed on the orientation pattern 105 is influenced by the orientation axis of the orientation pattern 105. For example, when the orientation pattern 105 has rotational symmetry or c-axis orientation crystallinity, the gallium nitride layer 106 also has c-axis orientation or (111) orientation crystallinity. The crystallinity of the gallium nitride layer 106 is preferably single crystal, but may be polycrystalline, microcrystalline, or nanocrystalline. The crystal structure of the gallium nitride layer 106 may have a wurtzite structure. The orientation of the gallium nitride layer 106 is preferably c-axis orientation or (111) orientation. The gallium nitride layer 106 may include an amorphous structure near the interface in contact with the orientation pattern 105, but preferably has crystallinity in the bulk.

The thickness of the gallium nitride layer 106 is not limited, and can be appropriately set according to the structure of the device. The gallium nitride layer 106 may have a single-layer structure, or may be a stacked structure including a plurality of layers having different conductivity types and/or compositions.

As shown in FIG. 3, the gallium nitride layer 106 formed on the orientation pattern 105 includes a first portion 106a reflecting the crystallinity of the orientation pattern 105 and a second portion 106b having a lower crystallinity than the first portion 106a. The first portion 106a is a portion located on a top surface 105a of the orientation pattern 105. The second portion 106b includes a portion located above a side surface (tapered portion) 105b of the orientation pattern 105 and a portion located above the base layer 102.

Since the crystallinity of the surface of the side surface 105b of the orientation pattern 105 is disturbed by etching, the crystallinity of the gallium nitride layer 106 in contact with that surface is also disturbed. The side surface 105b of the orientation pattern 105 also affects the gallium nitride layer 106 formed on the top surface 105a. Therefore, as shown in FIG. 3, the width of the first portion 106a is slightly narrower than the width of the top surface 105a. Furthermore, in FIG. 3, for convenience of explanation, although the boundary between the first portion 106a and the second portion 106b is clearly delimited, there may be a region between the first portion 106a and the second portion 106b in which the crystallinity is gradually disturbed from the first portion 106a toward the second portion 106b.

Next, as shown in FIG. 4, a resist mask 107 is formed so as to overlap the first portion 106a of the gallium nitride layer 106. That is, the resist mask 107 is arranged so as to pattern the first portion 106a of the gallium nitride layer 106 located on the top surface of the orientation pattern 105. In the present embodiment, although the side surface of the first portion 106a is shown to be consistent with the side surface of the resist mask 107, it is not limited to this example, and the width of the resist mask 107 may be narrower than the width of the first portion 106a.

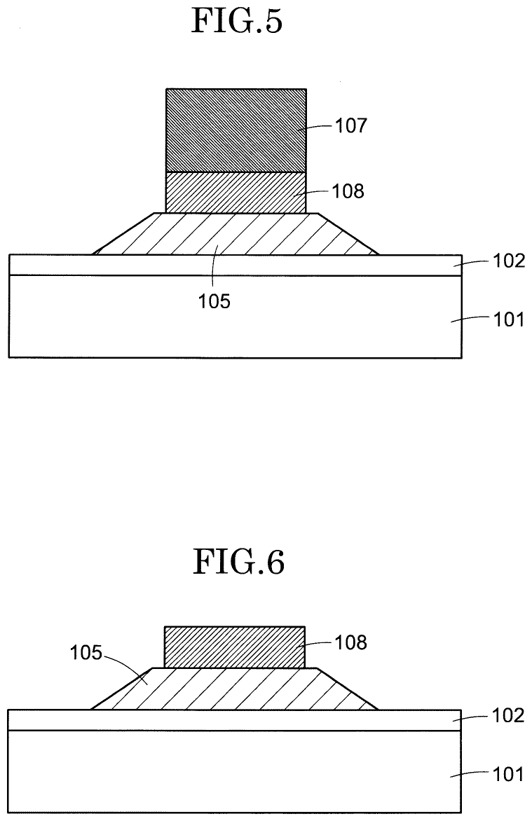

Next, as shown in FIG. 5, the gallium nitride layer 106 is etched using the resist mask 107 to form a semiconductor pattern 108. In the present embodiment, the dry etching method using a halogenated gas is used for etching the gallium nitride layer 106. However, the present invention is not limited to this example, and the semiconductor pattern 108 may be formed using the wet etching method.

Through the above processes, the semiconductor pattern 108 containing gallium nitride shown in FIG. 6 is obtained. Since the semiconductor pattern 108 of the present embodiment is formed by patterning the first portion 106a of the gallium nitride layer 106, the semiconductor pattern 108 has crystallinity aligned along a specific orientation axis reflecting the orientation of the orientation pattern 105. Therefore, by processing the semiconductor pattern 108 of the present embodiment and using it in the semiconductor device, it is possible to realize a semiconductor device having excellent characteristics.

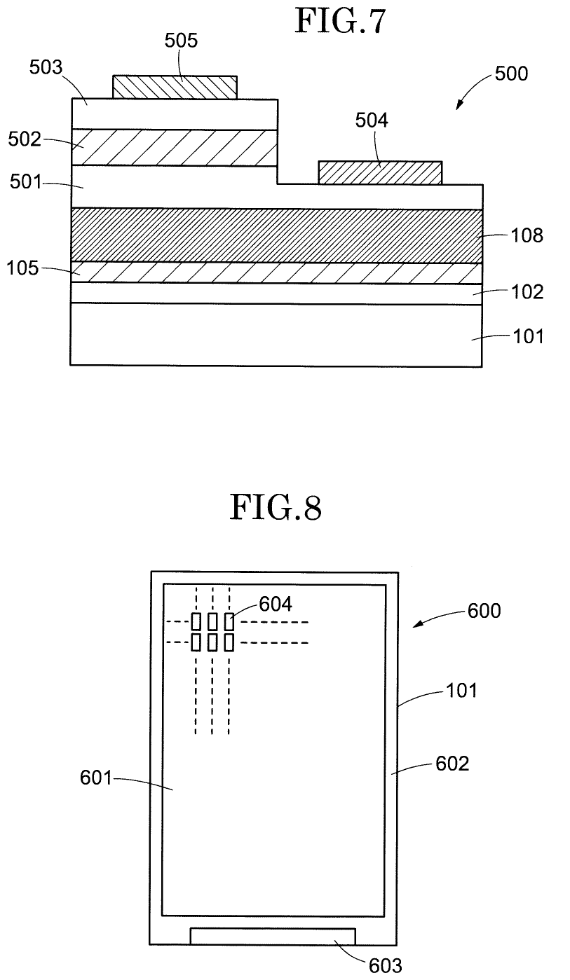

FIG. 7 is an end face view showing a semiconductor device 500 including the gallium nitride semiconductor layer according to the first embodiment. Specifically, the semiconductor device 500 shown in FIG. 7 is an example of the LED element manufactured using the semiconductor pattern 108 shown in FIG. 6. In addition, although the thickness relationship between the orientation pattern 105 and the semiconductor pattern 108 is different in FIG. 6 and FIG. 7, for convenience of explanation, the thickness of the orientation pattern 105 is merely exaggerated in FIG. 6.

As shown in FIG. 6, after the semiconductor pattern 108 is formed, an n-type gallium nitride layer 501, a light-emitting layer 502, and a p-type gallium nitride layer 503 are sequentially grown on the semiconductor pattern 108. Thereafter, parts of the n-type gallium nitride layer 501, the light-emitting layer 502, and the p-type gallium nitride layer 503 are removed so that the n-type gallium nitride layer 501 is exposed. Finally, an n-type electrode 504 and a p-type electrode 505 are formed in contact with the n-type gallium nitride layer 501 and the p-type gallium nitride layer 503, respectively.

Through the above processes, the semiconductor device 500 shown in FIG. 7 is completed. The semiconductor device 500 of the present embodiment is formed using the semiconductor pattern 108 using only the highly crystalline first portion 106a among the gallium nitride layer 106 formed on the amorphous substrate 101. Therefore, according to the present embodiment, the semiconductor device 500 can be manufactured on the inexpensive amorphous substrate 101. Further, according to the present embodiment, since the gallium nitride layer 106 having high crystallinity can be formed by the sputtering method, the semiconductor device 500 can be manufactured with high throughput without being exposed to a high temperature throughout the entire process.

The semiconductor device 500 shown in in FIG. 7 is merely an example of the LED element, and may be an LED element of another structure. For example, the light-emitting layer 502 may have a quantum-well structure in which a gallium nitride layer and an indium gallium nitride layer are alternately stacked.

FIG. 8 is a plan view showing a light-emitting device 600 using the semiconductor device 500 including the gallium nitride semiconductor layer according to the first embodiment. As shown in FIG. 8, a display portion 601 and a peripheral circuit portion 602 are arranged on the amorphous substrate 101. A terminal portion 603 for inputting various signals (video signals and control signals) to the light-emitting device 600 is arranged in a part of the peripheral circuit portion 602. A plurality of pixels 604 is arranged in a matrix inside the display portion 601. The semiconductor device 500 shown in FIG. 7 is arranged in each pixel 604. Although not shown, a semiconductor chip for controlling light emission and non-light emission of the semiconductor device 500 may be arranged in each pixel 604.

### Second Embodiment

In the present embodiment, an example of forming the gallium nitride layer using the orientation pattern formed by a method different from the first embodiment will be described. Furthermore, in the drawings, the same elements as those of the first embodiment are denoted by the same reference signs, and redundant description thereof will be omitted.

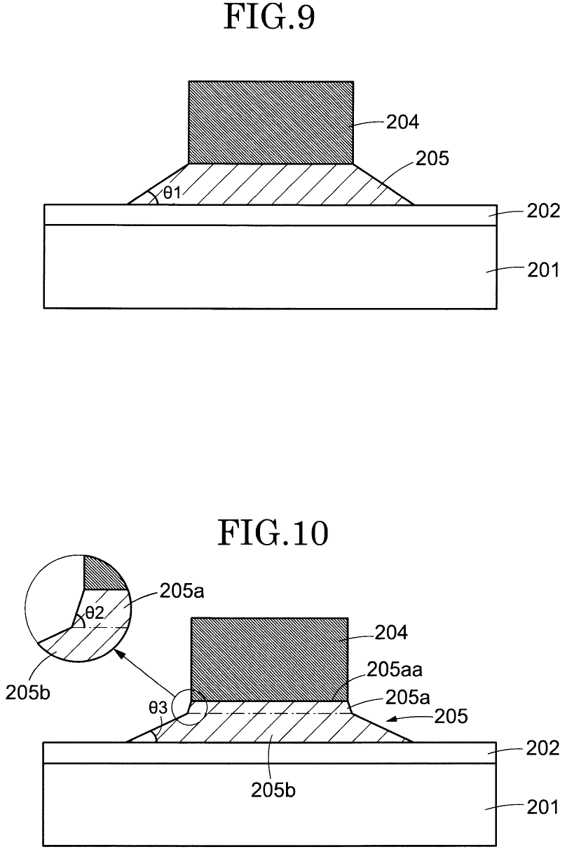

FIG. 9 to FIG. 14 are end face views showing a method for manufacturing a semiconductor device including a gallium nitride semiconductor layer according to the second embodiment. First, the state shown in FIG. 9 is obtained according to the process described with reference to FIG. 1 and FIG. 2 of the first embodiment. In FIG. 9, an amorphous substrate 201, a base layer 202, a resist mask 204, and an orientation pattern 205 correspond to the amorphous substrate 101, the base layer 102, the resist mask 104, and the orientation pattern 105 in FIG. 2, respectively.

As shown in FIG. 9, the orientation pattern 205 is formed by etching the gallium nitride layer (corresponding to the orientation layer 103 shown in FIG. 1) by the wet etching method. Therefore, the orientation pattern 205 has a tapered portion with the taper angle θ1. The taper angle θ1 of the orientation pattern 205 is 20° or more and 50° or less (preferably, 30° or more and 40° or less).

Next, as shown in FIG. 10, the orientation pattern 205 is etched using the resist mask 204 to form a first pattern portion 205a and a second pattern portion 205b. In FIG. 10, the dry etching method is used for etching the orientation pattern 205. That is, the orientation pattern 205 is additionally etched by the dry etching method, and the first pattern portion 205a having a steep taper portion is formed on the orientation pattern 205. The second pattern portion 205b is formed under the first pattern portion 205a by the process shown in FIG. 10. That is, the first pattern portion 205a and the second pattern portion 205b are made of the same material and are integrated.

In the present embodiment, the etching process is controlled so that the angle (taper angle θ2) of the side surface with respect to the bottom surface in the first patterned portion 205a is 70° or more and 90° or less (preferably, 75° or more and 85° or less). The bottom surface in the first pattern portion 205a is the interface between the first pattern portion 205a and the second pattern portion 205b. That is, the bottom surface in the first pattern portion 205a corresponds to a cut surface when the orientation pattern 205 is cut along the dashed-dotted line shown in FIG. 10. In this case, the angle (taper angle θ3) of the side surface with respect to the bottom surface in the second patterned portion 205b is smaller than the taper angle θ1 shown in FIG. 9, but the angle is preferably within a range of 20° or more and 50° or less (preferably, 30° or more and 40° or less). Furthermore, in the case where the angle of the side surface with respect to the bottom surface is 90° in the first patterned portion 205a, the angle is not strictly referred to as a taper angle, but for convenience of explanation, the angle is also referred to as a taper angle when the angle of the side surface with respect to the bottom surface is 90°.

Since the angle (taper angle) of the side surface with respect to the bottom surface is large in the first pattern portion 205a, the tapered portion is relatively small as compared with the second pattern portion 205b. Therefore, when forming the gallium nitride layer 206 to be described later, the gallium nitride layer 106 with good crystallinity can be formed over almost the entire top surface of the first pattern portion 205a without being affected by the tapered portion of the first pattern portion 205a. In addition, similar to the first embodiment, the second pattern portion 205b located below has a gently tapered portion, so that the etching residue (a residue of the gallium nitride layer 206) is less likely to be formed at the boundary between the base layer 202 and the orientation pattern 205 (strictly, the second pattern portion 205b).

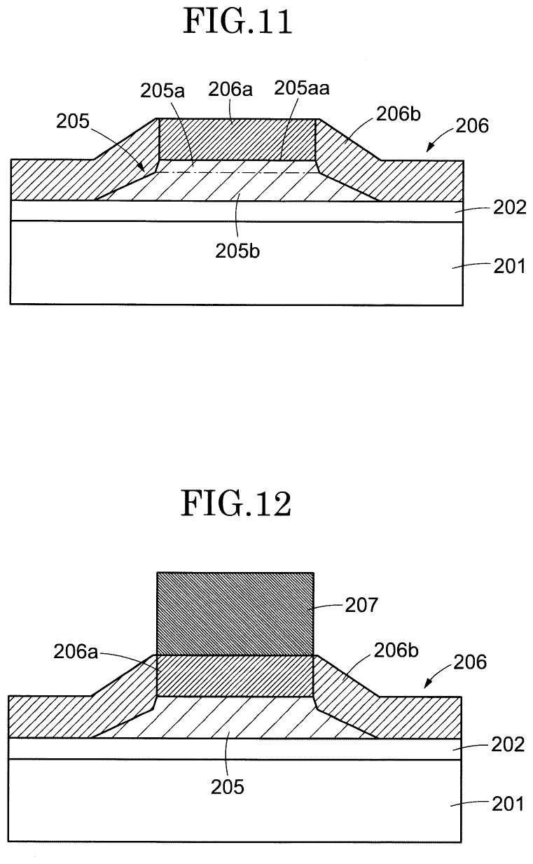

Next, as shown in FIG. 11, the gallium nitride layer 206 is formed to cover the orientation pattern 205. In the present embodiment, the gallium nitride layer 206 is formed as the semiconductor layer by the sputtering method. The gallium nitride layer 206 is influenced by the orientation axis of the orientation pattern 205 and includes a first portion 206a reflecting the crystallinity of the orientation pattern 205 and a second portion 206b having a lower crystallinity than the first portion 206a. In this case, as described above, in the present embodiment, since the angle of the edge of the first pattern portion 205a (the angle of the side surface with respect to the bottom surface) is steep, almost the entire region of the gallium nitride layer 206 overlapping a top surface 205aa of the first pattern portion 205a becomes the first portion 206a. Therefore, the gallium nitride layer 206 having excellent crystallinity (strictly, the first portion 206a of the gallium nitride layer 206) can be formed by effectively utilizing the top surface of the orientation pattern 205 (strictly, the top surface 205aa of the first pattern portion 205a).

Next, as shown in FIG. 12, a resist mask 207 is formed so as to overlap the first portion 206a of the gallium nitride layer 206. In the present embodiment, the resist mask 207 is arranged so as to pattern the first portion 206a formed on the top surface 205aa of the first pattern portion 205a in the gallium nitride layer 206.

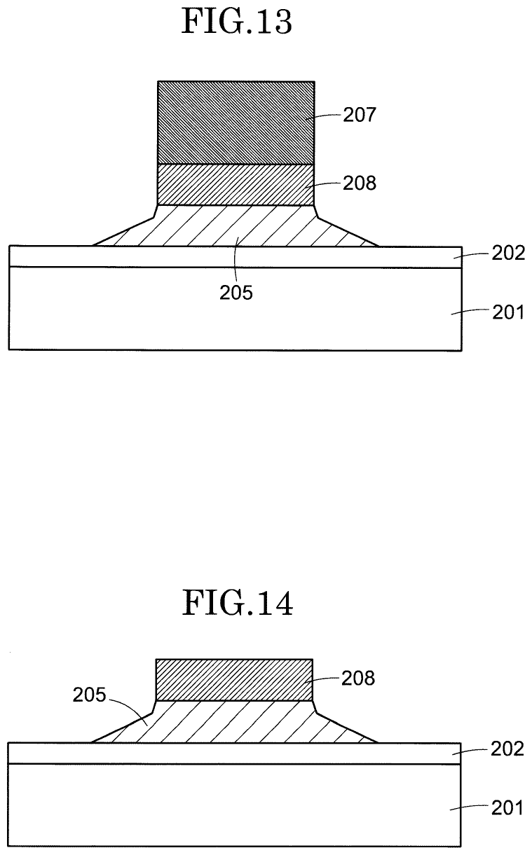

Next, as shown in FIG. 13, the gallium nitride layer 206 is etched using the resist mask 207 to form a semiconductor pattern 208.

Through the above processes, the semiconductor pattern 208 containing the gallium nitride shown in FIG. 14 is obtained. Since the semiconductor pattern 208 of the present embodiment is formed by patterning the first portion 206a of the gallium nitride layer 206, the semiconductor pattern 208 has crystallinity aligned along a specific orientation axis reflecting the orientation of the orientation pattern 205. Therefore, by processing the semiconductor pattern 208 of the present embodiment and using it in the semiconductor device as described in the first embodiment, it is possible to realize a semiconductor device having excellent characteristics.

### Third Embodiment

In the present embodiment, an example of forming the gallium nitride layer using the orientation pattern formed by a method different from the first embodiment will be described. Furthermore, in the drawings, the same elements as those of the first embodiment are denoted by the same reference signs, and redundant description thereof will be omitted.

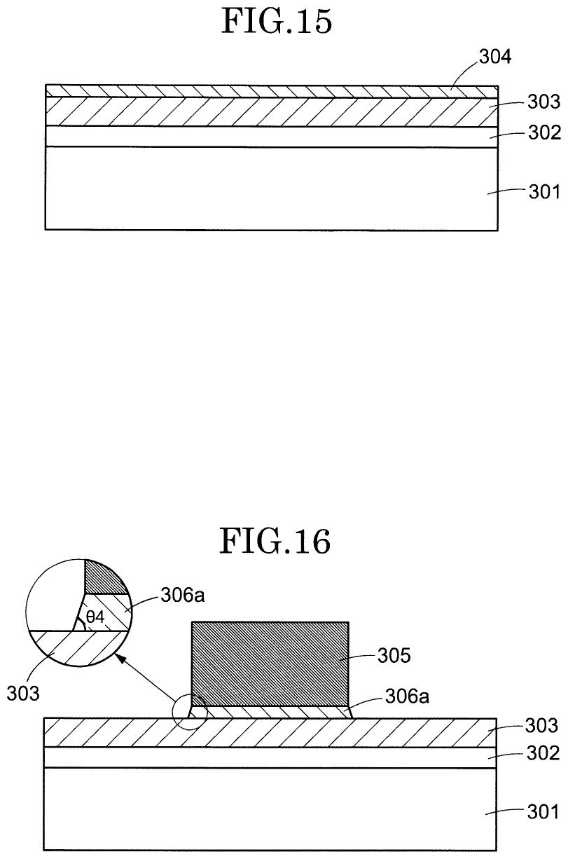

FIG. 15 to FIG. 21 are end face views showing a method for manufacturing a semiconductor device including a gallium nitride semiconductor layer according to the third embodiment. First, as shown in FIG. 15, a base layer 302 is formed on an amorphous substrate 301. In FIG. 15, the amorphous substrate 301 and the base layer 302 correspond to the amorphous substrate 101 and the base layer 102 in FIG. 1, respectively. After the base layer 302 is formed, a buffer layer 303 and an orientation layer 304 are sequentially formed on the base layer 302.

In the present embodiment, the buffer layer 303 has a function as an orientation layer on the lower layer side and a function as a buffer layer for adjusting the distance between the base layer 302 and the orientation layer 304. In the present embodiment, the buffer layer 303 is made of the same material as the orientation layer 304 in order to provide the buffer layer 303 with a function as the orientation layer. As will be described later, similar to the orientation pattern 105 of the first embodiment, the buffer layer 303 is patterned to have a gently tapered portion. Therefore, the thickness of the buffer layer 303 may be, for example, 50 nm or more (preferably, 50 nm or more and 100 nm or less). The buffer layer 303 may be a conductive layer or an insulating layer but is preferably a material that easily forms the gently tapered portion during patterning, which will be described later. In the present embodiment, an aluminum nitride layer is used as the buffer layer 303, but the present invention is not limited to this.

Similar to the orientation layer 103 of the first embodiment, the orientation layer 304 has a function of improving the orientation property of the crystal of a gallium nitride layer 307 when forming the gallium nitride layer 307 (see FIG. 18), which will be described later. In other words, the orientation layer 304 functions as the orientation layer on the upper layer side, and may be made of the same material as the orientation layer 103 of the first embodiment. In the present embodiment, a titanium layer is used as the orientation layer 304, but the present invention is not limited to this. In addition, the orientation layer 304 of the present embodiment may be thinner than the orientation layer 103 of the first embodiment. As described above, the thickness of the entire orientation pattern 306, which will be described later, is adjusted by the thickness of the buffer layer 303. That is, since the orientation layer 304 of the present embodiment does not need to form the gently tapered portion, it is only necessary to have a thickness sufficient to align the orientation axis of the gallium nitride layer 307. Specifically, in the present embodiment, the thickness of the orientation layer 304 is set to 10 nm or more and 30 nm or less, but the present invention is not limited to this example.

As described above, in the present embodiment, an aluminum nitride layer is used as the buffer layer 303, and a titanium layer is used as the orientation layer 304, thereby forming an orientation layer with a two-layer structure, but the present invention is not limited to this configuration. For example, a titanium layer may be used as the buffer layer 303, and an aluminum nitride layer may be used as the orientation layer 304.

Next, as shown in FIG. 16, the orientation layer 304 is etched using a resist mask 305 to form a first pattern portion 306a. The first pattern portion 306a has a tapered portion in which the angle of the side surface with respect to the bottom surface is θ4. In the present embodiment, since the dry etching method is used for etching the orientation layer 304, the taper angle θ4 of the first pattern portion 306a can be set to 70° or more and 90° or less (preferably, 75° or more and 85° or less). However, if it is possible to make the taper angle θ4 within the above-described range, the wet etching method may be used.

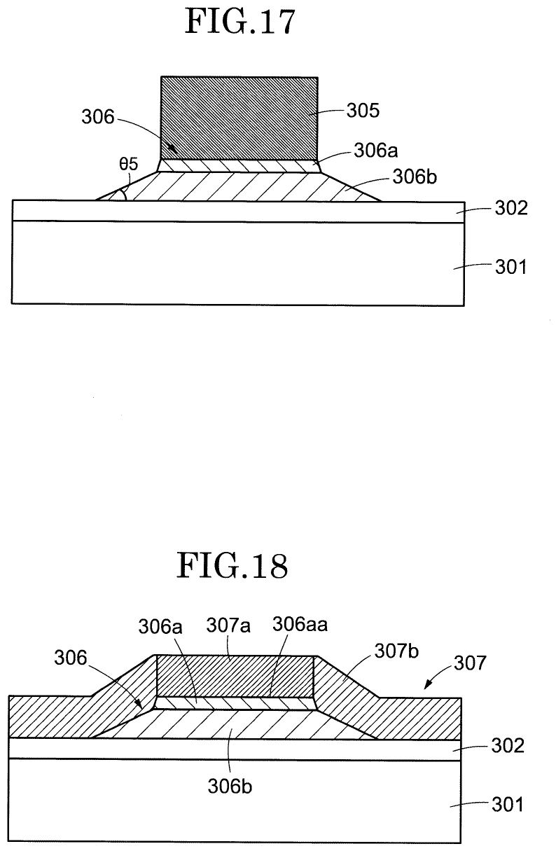

Next, as shown in FIG. 17, the buffer layer 303 is etched using the resist mask 305 to form a second pattern portion 306b. The second pattern portion 306b has a tapered portion in which the angle of the side surface with respect to the bottom surface is θ5. In the present embodiment, since the wet etching method is used for etching the buffer layer 303, the taper angle θ5 of the second pattern portion 306b can be set to 20° or more and 50° or less (preferably, 30° or more and 40° or less). However, if it is possible to make the taper angle θ5 within the above-described range, the dry etching method may be used.

As described above, the first pattern portion 306a and the second pattern portion 306b are formed by sequentially etching the orientation layer 304 and the buffer layer 303. In the present embodiment, the first pattern portion 306a and the second pattern portion 306b are collectively referred to as an orientation pattern 306. As described above, the orientation pattern 306 of the present embodiment is composed of the first pattern portion 306a in which the angle of the edge (the angle of the side surface with respect to the bottom surface) is steep and the second pattern portion 306b with the gently tapered portion.

In the first pattern portion 306a of the present embodiment, since the angle (taper angle) of the side surface is large, the tapered portion is relatively small as compared with the second pattern portion 306b. Therefore, when forming the gallium nitride layer 307 to be described later, the gallium nitride layer 307 with good crystallinity can be formed over almost the entire top surface of the first pattern portion 306a without being affected by the tapered portion of the first pattern portion 306a. In addition, similar to the first embodiment, the second pattern portion 306b located below has a gently tapered portion, so that the etching residue (a residue of the gallium nitride layer 307) is less likely to be formed at the boundary between the base layer 302 and the orientation pattern 306 (strictly, the second pattern portion 306b).

Next, as shown in FIG. 18, the gallium nitride layer 307 is formed to cover the orientation pattern 306. In the present embodiment, the gallium nitride layer 307 is formed as the semiconductor layer by the sputtering method. The gallium nitride layer 307 is influenced by the orientation axis of the orientation pattern 306 and includes a first portion 307 a reflecting the crystallinity of the orientation pattern 306 and a second portion 307b having a lower crystallinity than the first portion 307a. In this case, as described above, in the present embodiment, since the angle of the edge of the first pattern portion 306a is steep, almost the entire region of the gallium nitride layer 307 overlapping a top surface 306aa of the first pattern portion 306a becomes the first portion 307a. Therefore, the gallium nitride layer 307 having excellent crystallinity (strictly, the first portion 307a of the gallium nitride layer 307) can be formed by effectively utilizing the top surface of the orientation pattern 306 (strictly, the top surface 306aa of the first pattern portion 306a).

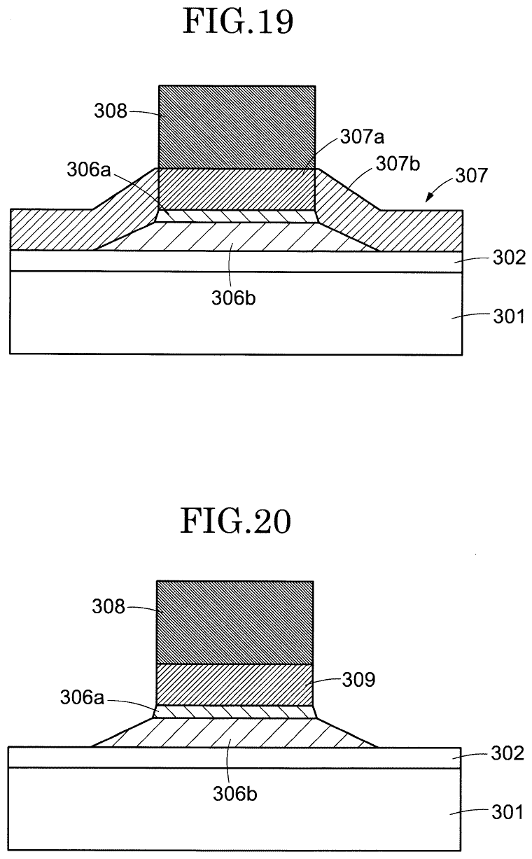

Next, as shown in FIG. 19, a resist mask 308 is formed so as to overlap the first portion 307a of the gallium nitride layer 307. In the present embodiment, the resist mask 308 is arranged so as to pattern the first portion 307a formed on the top surface 306aa of the first pattern portion 306a in the gallium nitride layer 307.

Next, as shown in FIG. 20, the gallium nitride layer 307 is etched using the resist mask 308 to form a semiconductor pattern 309.

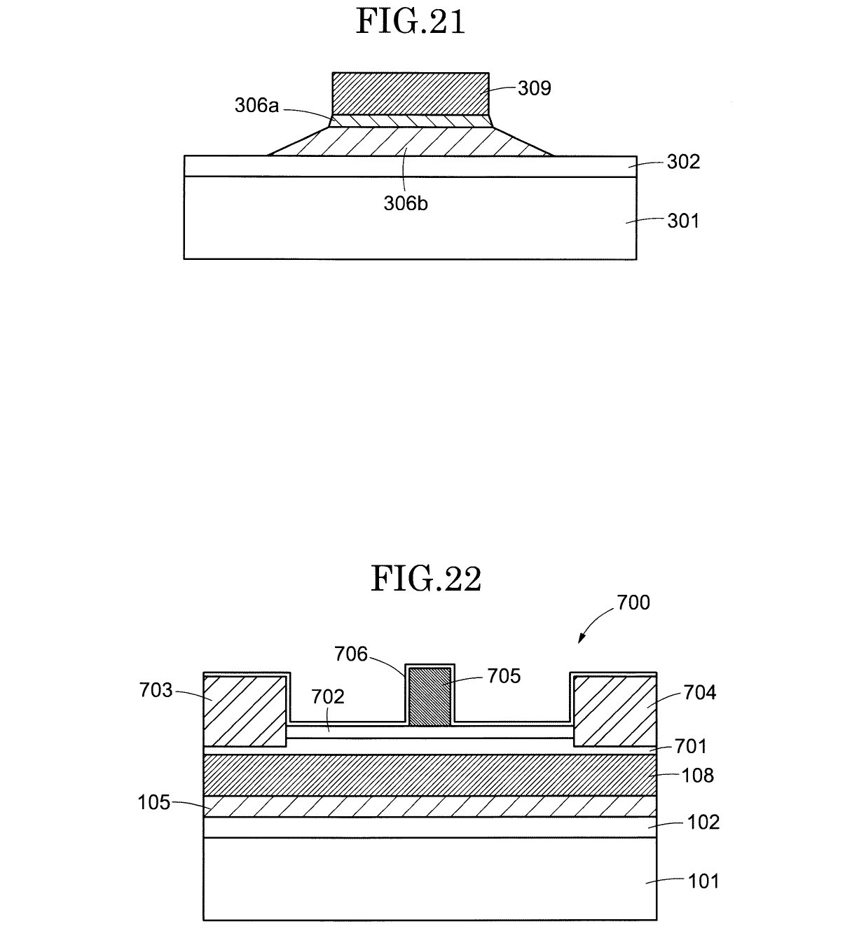

Through the above processes, the semiconductor pattern 309 containing gallium nitride shown in FIG. 21 is obtained. Since the semiconductor pattern 309 of the present embodiment is formed by patterning the first portion 307a of the gallium nitride layer 307, the semiconductor pattern 309 has crystallinity aligned along a specific orientation axis reflecting the orientation of the orientation pattern 306. Therefore, by processing the semiconductor pattern 309 of the present embodiment and using it in the semiconductor device as described in the first embodiment, it is possible to realize a semiconductor device having excellent characteristics.

### Fourth Embodiment

In the present embodiment, an example in which a semiconductor device is formed having a structure different from that of the first embodiment will be described. Specifically, in the present embodiment, an example in which the HEMT (High Electron Mobility Transistor) is formed as the semiconductor device will be described. Furthermore, in the drawings, the same elements as those of the first embodiment are denoted by the same reference signs, and redundant description thereof will be omitted.

FIG. 22 is an end face view showing a semiconductor device 700 including a gallium nitride semiconductor layer according to a fourth embodiment. Specifically, the semiconductor device 700 shown in FIG. 22 is an example of the HEMT manufactured using the semiconductor pattern 108 shown in FIG. 6 in the first embodiment. Furthermore, the thickness relationship between the orientation pattern 105 and the semiconductor pattern 108 is different in FIG. 6 and FIG. 22, but for convenience of explanation, the thickness of the orientation pattern 105 is merely exaggerated in FIG. 6.

An n-type aluminum gallium nitride layer 701 and an n-type gallium nitride layer 702 are sequentially formed on the semiconductor pattern 108 made of the gallium nitride layer. The sputtering method can be used to form the gallium nitride semiconductor layer. A trench reaching the n-type aluminum gallium nitride layer 701 is arranged in the n-type aluminum gallium nitride layer 701 and the n-type gallium nitride layer 702, and a source electrode 703 and a drain electrode 704 are arranged therein. A gate electrode 705 in contact with the n-type gallium nitride layer 702 is arranged between the source electrode 703 and the drain electrode 704. Finally, a silicon nitride layer 706 is formed as a protective layer, and the HEMT shown in FIG. 22 is completed.

The semiconductor device 700 of the present embodiment is formed using a highly crystalline gallium nitride layer (the semiconductor pattern 108) formed on the amorphous substrate 101. Therefore, according to the present embodiment, the semiconductor device 700 can be manufactured on the inexpensive amorphous substrate 101. Further, according to the present embodiment, since a plurality of gallium nitride semiconductor layers is formed by the sputtering method, the semiconductor device 700 can be manufactured with high throughput without being exposed to a high temperature throughout the entire process. In addition, the semiconductor device 700 shown in FIG. 22 is merely an example of the HEMT, and may be a HEMT of another structure.

Each of the embodiments described above as an embodiment of the present invention can be appropriately combined and implemented as long as no contradiction is caused. The addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
an amorphous substrate with an insulating surface;
an orientation pattern on the amorphous substrate; and
a semiconductor pattern including gallium nitride on a top surface of the orientation pattern, wherein
the orientation pattern includes a first pattern portion with a side surface having a first angle relative to a bottom surface, and a second pattern portion with a side surface having a second angle smaller than the first angle relative to the bottom surface and located lower than the first pattern portion.

2. The semiconductor device according to claim 1, wherein
the first pattern portion and the second pattern portion are integrated.

3. The semiconductor device according to claim 1, wherein
the first pattern portion and the second pattern portion are composed of different materials from each other.

4. The semiconductor device according to claim 1, wherein
the first angle is 70° or more and 90° or less, and
the second angle is 20° or more and 50° or less.

5. The semiconductor device according to claim 1, wherein
the first pattern portion is composed of a conductive layer with c-axis orientation.

6. The semiconductor device according to claim 1, wherein
the amorphous substrate is an amorphous glass substrate or a resin substrate.

7. A method for manufacturing a semiconductor device, the method comprising:
forming an orientation layer on an amorphous substrate having an insulating surface;
forming an orientation pattern having an inclined side surface with respect to a bottom surface by wet etching the orientation layer;
forming a semiconductor layer including gallium nitride on the insulating surface and the orientation pattern; and
forming a semiconductor pattern on a top surface of the orientation pattern by etching the semiconductor layer including gallium nitride.

8. The method according to claim 7, wherein
the angle of the side surface relative to the bottom surface is 20° or more and 50° or less.

9. The method according to claim 7, wherein
the orientation layer is a conductive layer with c-axis orientation.

10. The method according to claim 7, wherein
the amorphous substrate is an amorphous glass substrate or a resin substrate.

11. The method according to claim 7, wherein
the semiconductor layer including gallium nitride is formed by sputtering.

12. The method according to claim 7 further comprising:
after forming an orientation pattern having an inclined side surface, forming a first pattern portion with a side surface having a first angle relative to a bottom surface, and a second pattern portion with a side surface having a second angle smaller than the first angle relative to the bottom surface and located lower than the first pattern portion by dry etching the orientation pattern.

13. The method according to claim 12, wherein
the first angle is 70° or more and 90° or less, and
the second angle is 20° or more and 50° or less.

14. The method according to claim 12, wherein
the orientation layer is a conductive layer with c-axis orientation.

15. The method according to claim 12, wherein
the semiconductor layer including gallium nitride is formed by sputtering.

16. A method for manufacturing a semiconductor device, the method comprising:
forming a buffer layer on an amorphous substrate having an insulating surface;
forming an orientation layer on the buffer layer, the orientation layer being made of a different material from the buffer layer;
forming a first pattern portion with an inclined side surface having a first angle with respect to a bottom surface by etching the orientation layer;
forming a second pattern portion with an inclined side surface having a second angle smaller than the first angle with respect to the bottom surface by etching the buffer layer;
forming a semiconductor layer including gallium nitride on the insulating surface, the first pattern portion and the second pattern portion; and
forming a semiconductor pattern on a top surface of the first pattern portion by etching the semiconductor layer including gallium nitride.

17. The method according to claim 16, wherein
the first angle is 70° or more and 90° or less, and
the second angle is 20° or more and 50° or less.

18. The method according to claim 16, wherein
the orientation layer is a conductive layer with c-axis orientation.

19. The method according to claim 16, wherein
the amorphous substrate is an amorphous glass substrate or a resin substrate.

20. The method according to claim 16, wherein
the semiconductor layer including gallium nitride is formed by sputtering.
